(19) United States
(12) Patent Application Publication
(10) Pub. No.: US 2015/0086755 A1
(43) Pub. Date: Mar. 26, 2015

(54) PHOTOCURED PRODUCT

(71) Applicant: CANON KABUSHIKI KAISHA, Tokyo (JP)

(72) Inventors: Chieko Mihara, Isehara-shi (JP); Toshiki Ito, Kawasaki-shi (JP); Yohei Murayama, Kawasaki-shi (JP); Motoki Okinaka, Inagi-shi (JP)

(21) Appl. No.: 14/402,806

(22) PCT Filed: May 21, 2013
(86) PCT No.: PCT/JP2013/064564

§ 371 Date: Nov. 21, 2014

(30) Foreign Application Priority Data
Jun. 4, 2012 (JP) 2012-126821

(51) Int. Cl. H05K 3/10; H05K 1/03; C08J 5/00

(52) U.S. Cl. CPC H05K 3/10; C08J 5/00; H05K 1/0373; C08J 2335/02
USPC 428/195.1; 524/376; 522/39; 264/447; 216/13; 427/526

(57) ABSTRACT

To provide a photocured product having small mold releasing force. A photocured product obtained by curing with light and containing a surface active agent, wherein a peak area of the ether bond derived peak is 3.0 times or more as large as a peak area of the ester bond derived peak, wherein the peak areas are obtained by peak separation processing by curve fitting of an X-ray photoelectron spectroscopy spectrum obtained as an analytical result on a chemical state of carbon at topmost surface of the photocured product, the analytical result being among analytical results on the topmost surface of the photocured product obtained by surface analysis of the photocured product with angle resolved X-ray photoelectron spectroscopy.

### TECHNICAL FIELD

The present invention relates to a photocured product.

### BACKGROUND ART

Semiconductor integrated circuits have been developed to attain higher compactness and higher integration. Photolithographic process (photolithographic technique) has been employed and as a pattern formation technique applicable to microprocessing for realizing high compactness and high integration. Photolithography apparatuses used for the photolithographic process have been recently improved for attaining higher accuracy. Since desired processing accuracy has come close to a diffraction limit of exposure light, however, the photolithographic technique has also come close to the limit thereof.

Accordingly, as a method for attaining further higher compactness and further higher accuracy, a photo-imprinting method has been proposed. In a photo-imprinting method, a mold having a fine protruding and recessed pattern thereon is pressed against a substrate having a photocurable composition applied thereon for transferring the protrusion and recession of the mold onto the photocurable composition applied on the substrate.

Attention is especially paid to a photo-imprinting method. In a photo-imprinting method, a mold transparent to exposure light is brought into contact with a photocurable composition applied on a substrate, the photocurable composition is cured by light irradiation, and the mold is detached from the thus cured product so as to form a fine pattern attached onto the substrate.

PTL 1 discloses a photocured product for imprinting including a deep layer disposed close to a substrate and a surface layer disposed on the deep layer and having a larger content of a fluorine compound than in the deep layer. It is stated that surface energy of the photocured product of PTL 1 is lowered because of the fluorine compound included in the surface layer and hence mold releasing force necessary for detaching the photocured product from a mold can be reduced. On the other hand, PTL 2 discloses a photocurable composition for photo-imprinting including at least one polymerizable monomer, a photopolymerization initiator and a fluorine atom-containing surface active agent. PTL 2 states that the mold releasing force may be reduced in the same manner as described in PTL 1 because the photocurable composition including the fluorine atom-containing surface active agent is used as a mask processing method for providing desired wettability and releasability between a mask and a polymerizable composition.

### CITATION LIST

### Patent Literature

PTL 1: Japanese Patent Application Laid-Open No. 2006-080447
PTL 2: U.S. Pat. No. 7,837,921

### Non Patent Literature

NPL 1: Handbook of X-ray Photoelectron Spectroscopy, edited by Physical Electronics, Inc.

### SUMMARY OF INVENTION

### Technical Problem

Such photo-imprinting techniques have, however, a plurality of problems that cannot be solved by the conventional photo-imprinting methods. One of the problems is reduction of force necessary for releasing a mold from a cured product, namely, mold releasing force. When the mold releasing force is large, there may arise a problem in which a defect is caused in a pattern formed in a cured product or alignment accuracy is lowered because a substrate loses touch with a stage.

The effect of reducing the mold releasing force attained by the methods disclosed in PTL 1 and PTL 2 is not sufficient. Besides, neither PTL 1 nor PTL 2 presented analysis data related to a thickness or an amount of a segregated fluorine portion in the composition including fluorine or a surface active agent segregated to a surface side along a depth direction.

The present invention was achieved in consideration of the aforementioned problems, and an object of the present invention is to provide a photocured product having small mold releasing force.

### Solution to Problem

A photocured product of the present invention is a photocured product obtained by curing with light, containing a surface active agent, wherein a peak area of an ether bond derived peak is 3.0 times or more as large as a peak area of an ester bond derived peak, wherein the peak areas are obtained by waveform separation processing of an X-ray photoelectron spectroscopy spectrum obtained as an analytical result on a chemical state of carbon at a topmost surface of the photocured product, the analysis result being among analytical results on the topmost surface of the photocured product obtained by surface analysis of the photocured product with angle resolved X-ray photoelectron spectroscopy.

Further features of the present invention will become apparent from the following description of exemplary embodiments with reference to the attached drawings.

### BRIEF DESCRIPTION OF DRAWINGS

FIGS. 1A, 1B1, 1B2, 1C, 1D, 1E and 1F are schematic cross-sectional views illustrating production process for a photocured product and a circuit board in a production method of the present invention.

FIG. 2 is a diagram illustrating a result of AR-XPS measurement along a depth direction of a photocured product prepared in Example 1.

FIG. 3 is a diagram illustrating a result of AR-XPS measurement along a depth direction of a photocured product prepared in Example 2.

FIG. 4 is a diagram illustrating a result of AR-XPS measurement along a depth direction of a photocured product prepared in Comparative Example 1.

FIG. 5 is a graph illustrating a relationship between a peak area ratio (C—O—C/O—C═O) obtained based on the AR-XPS measurement and molding releasing force of a layered body.

### DESCRIPTION OF EMBODIMENTS

An embodiment of the present invention will now be described in detail. The present invention is not limited to the embodiment described below but includes appropriate changes and modifications of the following embodiment made without departing from the scope of the invention based on general knowledge of those skilled in the art.

A photocured product of the present invention is a photocured product obtained by curing with light, and contains a surface active agent. Besides, the photocured product of the present invention is characterized by a composition at a surface thereof. Information on the surface composition of the photocured product of the present invention is obtained by surface analysis (of the photocured product) with angle resolved X-ray photoelectron spectroscopy. This information is, specifically, information on two kinds of peaks obtained by peak separation processing by curve fitting on an X-ray photoelectron spectroscopy spectrum obtained as an analytical result on a chemical state of carbon at a topmost surface of the photocured product, the analytical result being among analytical results on the topmost surface of the photocured product. Specifically, the information is information on the ether bond derived peak and the ester bond derived peak. According to the present invention, when the ether bond derived peak is compared with the ester bond derived peak, the ether bond derived peak has a peak area 3.0 times or more as large as a peak area of the ester bond derived peak.

The photocured product of the present invention is produced by employing, for example, a photo-imprinting method, but the technique employed in the present invention is not limited to the photo-imprinting method. If the photo-imprinting method is employed in the present invention, a photocured product having a pattern of protrusion or recession of a millimeter level, a micrometer level (including a sub-micrometer level) or a nanometer level (1 nm to 100 nm) can be produced. If the photo-imprinting method is employed, a pattern with a size of preferably 1 nm to 10 mm is formed. More preferably, a pattern with a size of 10 nm to 100 μm is formed.

Now, the details of the photocured product of the present invention will be described.

The photocured product of the present invention is obtained by irradiating, with light, a photocurable composition containing a surface active agent. The detailed composition of the photocurable composition and the details of the surface active agent included in the photocurable composition will be described later.

In the photocured product of the present invention, physical properties largely affecting mold releasing force against a mold, such as surface properties, can be evaluated by angle resolved X-ray photoelectron spectroscopy analysis (XPS analysis).

The XPS analysis is a technique in which a surface of a solid is excited by X-ray irradiation for analyzing energy of photoelectrons released from the surface. Besides, in angle resolved X-ray photoelectron spectroscopy (AR-XPS), an angle for detecting photoelectrons excited by X-rays is varied. Thus, an effective detection depth can be changed. Therefore, in the AR-XPS, information on a surface along a depth direction, more specifically information on a near surface (with a depth of approximately 10 nm or less from a topmost surface) along the depth direction can be nondestructively obtained without performing sputtering or the like. Furthermore, when an angle for taking out photoelectrons is set to be small, information on elements and chemical bonds present in a portion closer to the surface can be obtained, and thus, chemical species (functional groups) and compositions present at surface can be estimated.

Here, the photocured product of the present invention principally includes an organic compound. Therefore, when the chemical state of carbon present at the topmost surface of the photocured product is analyzed/evaluated by the XPS analysis, for example, information on the types and the amounts of functional groups including carbon atoms at the topmost surface is obtained in the form of a spectrum having a plurality of peaks. Specifically, the types of functional groups may be analyzed based on peak positions in the spectrum, and the amounts of functional groups may be analyzed based on peak areas in the spectrum. In high-energy resolution XPS measurement using a monochrome X-ray source in particular, respective peaks can be distinguished from one another, and the numbers of elements involved in functional groups and bonds may be quantitatively determined by performing waveform separation of the respective peaks.

In the photocured product of the present invention, information on functional groups including carbon atoms present at the topmost surface of the photocured product, specifically, information on the ether bond (—C—O—C—) and the ester bond (—C(═O)—O—) can be obtained by the XPS analysis in the form of a spectrum. This is because a C—C bond, a C—O bond and a C═O bond respectively have peculiar chemical shifts in a C is spectrum of an organic compound. Therefore, when this spectrum is subjected to the waveform separation, information on the relative amounts of functional groups including carbon atoms, such as the ether bond and the ester bond, present at the topmost surface of the photocured product can be obtained based on peak areas of a plurality of peaks included in the spectrum. In the photocured product of the present invention, information on the ether bond that can be confirmed by the XPS analysis can be regarded principally as information on the ether bond included in the surface active agent. In other words, the information on the ether bond also corresponds to information for supporting, by the XPS analysis, the presence of the surface active agent at surface of the photocured product. On the other hand, in the photocured product of the present invention, information on the ester bond that can be confirmed by the XPS analysis can be regarded principally as information on the ester bond included in a monomer used as a base material of the photocured product. In other words, the information on the ester bond also corresponds to information for supporting, by the XPS analysis, the presence of a monomer having the ester bond at surface of the photocured product. Here, examples of the monomer having the ester bond include monomers having acrylate (—CH₂═CH—C(═O)—O—) or methacrylate (—CH₂═C(CH₃)—C(═O)—O—).

In the photocured product of the present invention, a peak area of the ether bond derived peak is 3.0 times or more as large as a peak area of the ester bond derived peak. This means that a compound having the ether bond, for example, a surface active agent is unevenly distributed at surface of the photocured product of the present invention.

The present inventors have found that mold releasing force can be further reduced by unevenly distributing an EO group (—CH₂—CH₂—O—) and a PO group (—CH₂—CH₂—CH₂—O—) both having the ether bond at the topmost surface of the photocured product than by employing the conventionally noted surface segregation of elemental fluorine. Furthermore, it has been conventionally considered that the mold releasability is improved by unevenly distributing a surface active agent in a larger amount at surface. As a result of the AR-XPS analysis performed by the present inventors, however, it has been found that there is an optimum value of the amount of surface active agent to be unevenly distributed in a photocured product. In other words, it has been found that the mold releasing force is not always reduced but may be increased on the contrary by increasing the amount of surface active agent unevenly distributed in the photocured product. Moreover, it has been found that the mold releasing force is more largely reduced when the EO/PO groups having the ether bond are added in a prescribed concentration on the surface of the photocured product than when the concentration of a fluorine-containing substituent is increased. Besides, it has been found that the EO group is more preferable than the PO group in a substituent having the ether bond (such as alkylene oxide) from the viewpoint of the mold releasing force.

Taking the above into consideration, in order to reduce the mold releasing force of a photocured product against a mold, it is necessary to make the ether bond present in a larger amount than the ester bond at surface of the photocured product. Quantitatively considering, the peak area of the ether bond derived peak obtained by the XPS analysis such as the AR-XPS may be 3.0 times or more, preferably 4 times or more and more preferably 4 times or more and 20 times or less as large as the peak area of the ester bond derived peak.

In the photocured product of the present invention, however, functional groups that may be present at surface of the photocured product are not limited to the substituent having an ether bond and the substituent having an ester bond described above.

The reason why the mold releasability of the photocured product of the present invention is thus improved has not become clear in detailed mechanism, but the present inventors have found that the mold releasing force can be reduced by optimizing the structure and an added concentration of a surface active agent functioning as a mold releasing agent.

When a ratio occupied by an ethylene oxide portion in a molecular constitution at surface of the photocured product is increased by, for example, unevenly distributing a surface active agent at surface of the photocured product, some hypotheses may be set up from the viewpoint of affinity between ethylene oxide and other partial structures and a lamellar layer formed by the surface active agent.

For example, alkylene oxide (EO/PO groups) that has the ether bond and is a hydrophilic molecular unit has low affinity with a resist monomer (a polymerizable monomer) but high affinity with quartz, and therefore, the following hypothesis may be set up.

The surface active agent comes between quartz (a mold) and a monomer (a polymerizable monomer) and forms a lamellar layer therein, so that an interface can be formed between the monomer and a portion including fluorine atoms of the surface active agent adhered onto the mold. At this point, it may be hypothesized that the mold releasing force is reduced because affinity between the portion including fluorine atoms and monomer molecules is low.

Furthermore, when a surface active agent is unevenly distributed at surface of a photocured product, if the surface active agent is unevenly distributed in a prescribed amount (having what is called an optimum value) in the whole surface of the photocured product, the resulting structure is known to become energetically the most stable in terms of, for example, balance between hydrophilicity and hydrophobicity. This is probably for the following reason: if the amount of surface active agent included in the photocurable composition is smaller than the minimum necessary amount for forming a lamellar layer in the whole surface of the photocured product, the surface active agent cannot sufficiently cover the surface of the photocured product, and hence the mold releasability cannot be expected to largely improve. On the other hand, when the amount of surface active agent included in the photocurable composition exceeds an upper limit of an amount optimal for stably forming a lamellar layer, the surface active agent cannot form a regular lamellar layer structure, and hence it is expected that a regular interface cannot be formed. Accordingly, a hypothesis that mold releasing force is reduced by appropriately adjusting the amount of surface active agent optimal for forming a regular lamellar layer by the surface active agent can be set up.

### (AR-XPS Analysis)

Next, the AR-XPS analysis and a specific measurement method will be described.

As the XPS employed in analyzing the surface of the photocured product of the present invention, an apparatus commercially available generally as a surface analysis apparatus may be used, and a surface analysis apparatus having a data processing function for conducting approximate calculation can be used.

The AR-XPS analysis is a method in which a detection depth is changed by changing a take-off angle (TOA) of a detector as described above. The TOA can be generally inclined (adjusted) in a range from 5 degrees to 90 degrees. When the TOA is smaller, information on a portion closer to the topmost surface can be obtained.

In actual measurement, the TOA and the cumulative number may be determined depending upon the film thickness of the photocured product and the extent of damage caused in fluorocarbon that can be included in the surface active agent.

Although varied depending upon a measurement sample, as the TOA is smaller, the signal intensity is lowered. Therefore, for the AR-XPS analysis of the topmost surface, the measurement can be performed with the TOA set to a range from 5 degrees to 15 degrees.

Furthermore, in order to reduce damage caused during the measurement, measurement conditions can be determined so as to reduce charge-up as much as possible by, for example, setting Ar ions used for neutralization to a low voltage.

Bond energy employed in chemical state analysis of carbon C1s may be obtained by referring to values cited in a literature (NPL 1). Specific values are as follows:

### C—C (Graphite): φ; 284.5 eV, NIST; 285 eV

### PEO(—CH₂C*H₂O—): φ; 284.5 eV

p(CH₃OC*OCH═CH₂): φ; 288.6 eV
p(C*F₂—CH₂): φ; 290.8 eV, NIST; 290.9 eV
p(C*F₃): φ; 294.7 eV

For the waveform processing (peak resolution) performed after the measurement, analysis can be performed by using Multi Pack manufactured by Ulvac-Phi, Inc. or the like. Incidentally, the AR-XPS measurement described so far can be conducted in a plurality of regions in consideration of an in-plane distribution on the sample surface so as to obtain an average of measured values.

### (Surface Active Agent)

The photocured product of the present invention includes a surface active agent. In the present invention, the surface active agent may be any one of a nonionic surface active agent, a cationic surface active agent and an anionic surface active agent. The surface active agent is preferably a compound containing a fluorine atom or a compound containing an ethylene oxide skeleton. More preferably, the surface active agent is a compound containing a fluorine atom and a compound containing an ethylene oxide skeleton. Compounds suitably used as the surface active agent will be described later.

The surface active agent included in the photocured product of the present invention can be principally unevenly distributed at surface of the photocured product specifically by any one of the following methods (i) to (iii):

(i) A method in which the surface active agent is precedently contained in the photocurable composition;
(ii) a method in which the surface active agent is precedently applied to a surface of a mold so as to be transferred onto the surface of the photocurable composition in bringing the mold into contact with the photocurable composition; and
(iii) a method in which the surface active agent is precedently applied to a surface of a mold and is transferred onto the surface of the photocurable composition at the time of light irradiation or mold release after the mold is brought into contact with the photocurable composition.

When any of the aforementioned methods (i) to (iii) is employed, the surface active agent is present in the form of a thin film on the interface between the photocured product and the mold. Furthermore, it seems that the mold releasing force can be reduced because the surface energy is lowered by a fluorine atom.

The surface active agent included in the photocured product of the present invention can be a compound represented by the following Formula [1]:

R₁-x₁-R₂-x₂-R₃ [1]

In Formula [1], R₁ represents a perfluoroalkyl group. Specific examples of the perfluoroalkyl group represented by R₁ include straight alkyl groups having 2 to 20 carbon atoms in which all hydrogen atoms are substituted by fluorine atoms, such as a perfluoroethyl group, a perfluoropropyl group, a perfluorobutyl group, a perfluoropentyl group, a perfluorohexyl group, a perfluoroheptyl group, a perfluorooctyl group, a perfluorononyl group and a perfluorodecyl group. From the viewpoint of environmental safety, the carbon number of the perfluoroalkyl group can be 7 or less.

In Formula [1], R₂ represents a bivalent substituent including ethylene oxide. Here, a bivalent substituent including ethylene oxide is specifically a bivalent substituent of either of the following chains (i) and (ii):

(i) A polyalkylene oxide chain including ethylene oxide; and
(ii) an alkyl chain including ethylene oxide.

Specific examples of the chain (i) include a polyethylene oxide chain having 1 to 100 repeating units, and a polypropylene oxide chain (—CH₂CH(CH₃)O—) having 1 to 100 repeating units.

Specific examples of the chain (ii) include a polymer chain including a polyethylene oxide chain having 1 to 100 repeating units and a straight alkyl group having 2 to 100 carbon atoms, and a polymer chain including a polyethylene oxide chain having 1 to 100 repeating units and an alkyl group including a cyclic structure.

In Formula [1], R₃ represents a polar functional group. Examples of the polar functional group represented by R₃ include an alkyl hydroxyl group, a carboxyl group, a thiol group, a pyridyl group, a silanol group and a sulfo group.

In Formula [1], x₁ and x₂ each represent a single-bonded or bivalent substituent. If either of x₁ and x₂ is a bivalent substituent, specific examples of the substituent include an alkylene group, a phenylene group, a naphthylene group, an ester group, an ether group, a thioether group, a sulfonyl group, a secondary amino group, a tertiary amino group, an amide group and a urethane group.

Incidentally, one of surface active agents may be singly used or two or more of surface active agents may be used together.

A blending ratio of the fluorine atom-containing surface active agent included in the photocurable composition of the present invention is determined based on the total amount of a polymerizable monomer (a component A) included in the photocurable composition. Specifically, the blending ratio is 0.001% by weight to 5% by weight, preferably 0.002% by weight to 4% by weight and more preferably 0.005% by weight to 3% by weight of the total amount of the component A.

Method for Producing Photocured Product

Next, a method for producing the photocured product of the present invention will be described with appropriate reference to the accompanying drawings. Production process for the photocured product of the present invention includes at least the following steps (A) to (C):

(A) An applying step of applying a photocurable composition onto a substrate;
(B) a curing step of bringing a mold having a prescribed pattern shape into contact with the photocurable composition and curing the photocurable composition by irradiating the photocurable composition with light through the mold; and
(C) a mold releasing step of releasing the photocurable composition from the mold.

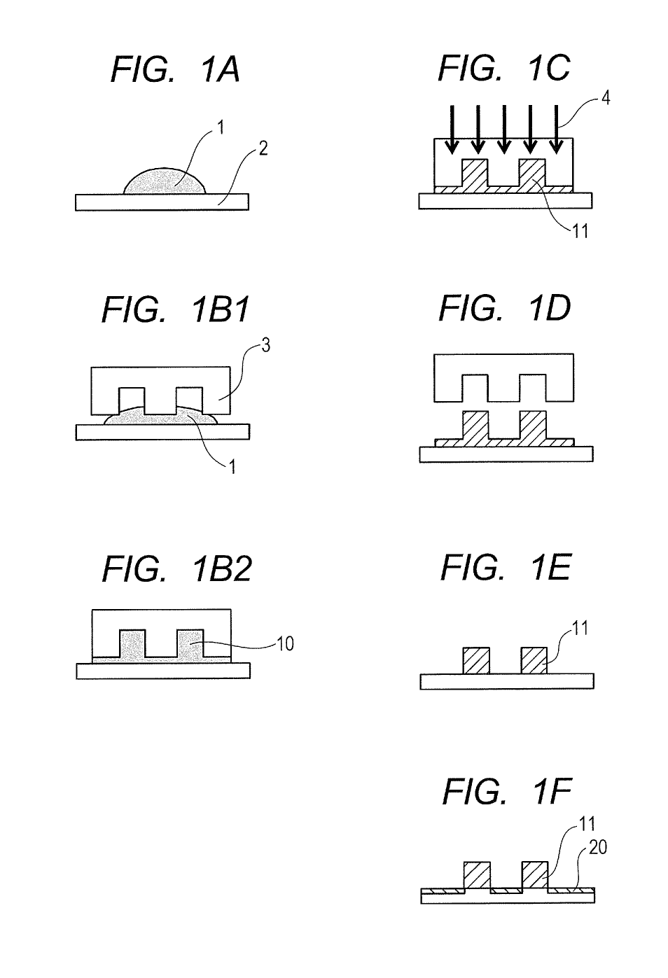

FIGS. 1A to 1F are schematic cross-sectional view illustrating the production process for the photocured product and a circuit board according to a production method of the present invention. The production process illustrated in FIGS. 1A to 1F includes the following steps (1) to (5) or (6):

(1) An applying step (FIG. 1A);
(2) a contact step (FIGS. 1B1, 1B2);
(3) a light irradiation step (FIG. 1C);
(4) a mold releasing step (FIG. 1D);
(5) an etching step (FIG. 1E); and
(6) a substrate processing step (FIG. 1F).

Through the steps (1) to (6) (or through the steps (1) to (5)), a photocured product 11 and an electronic component (an electronic device) or an optical component including the photocured product 11 can be produced from a photocurable composition 1. The details of the respective steps will now be described.

### (1) Applying Step

First, the photocurable composition 1 is applied onto a substrate 2 (FIG. 1A). Here, the photocurable composition is a composition including the following components (1-1) to (1-3):

(1-1) A photocurable component cured with light;
(1-2) a curing aid for aiding curing of the photocurable component; and
(1-3) a surface active agent.

### (1-1) Photocurable Component

In the present invention, a photocurable component means a component cured through a reaction of crosslinkage, polymerization or the like when irradiated with light. More specifically, a photocurable component is a photopolymerizable monomer that is polymerized, when irradiated with light, through a self-reaction or a reaction with radicals, cations or anions produced from the curing aid described later.

Examples of the photopolymerizable monomer include a radical polymerizable monomer and a cation polymerizable monomer.

### (Radical Polymerizable Monomer)

The radical polymerizable monomer can be a compound having one or more acryloyl or methacryloyl groups.

Examples of a monofunctional (meth)acrylic compound having one acryloyl or methacryloyl group include, but are not limited to, phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of p-cumylphenol reacted with ethylene oxide, 2-bromophenoxyethyl (meth)acrylate, 2,4-dibromophenoxyethyl (meth)acrylate, 2,4,6-tribromophenoxyethyl (meth)acrylate, phenoxy (meth)acrylate in which a plurality of moles of ethylene oxide or propylene oxide are modified, polyoxyethylene nonylphenyl ether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloyl morpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl

(meth)acrylate, butyl (meth)acrylate, amyl

(meth)acrylate, isobutyl (meth)acrylate, t-butyl

(meth)acrylate, pentyl (meth)acrylate, isoamyl

(meth)acrylate, hexyl (meth)acrylate, heptyl

(meth)acrylate, octyl (meth)acrylate, isooctyl

(meth)acrylate, 2-ethylhexyl (meth)acrylate, nonyl

(meth)acrylate, decyl (meth)acrylate, isodecyl

(meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxy ethyl (meth)acrylate, ethoxy diethylene glycol (meth)acrylate, polyethylene glycol mono(meth)acrylate, polypropylene glycol mono (meth)acrylate, methoxy ethylene glycol (meth)acrylate, ethoxy ethyl (meth)acrylate, methoxy polyethylene glycol (meth)acrylate, methoxy polypropylene glycol (meth)acrylate, diacetone (meth) acrylamide, isobutoxy methyl (meth) acrylamide, N,N-dimethyl (meth) acrylamide, t-octyl (meth)acrylamide, dimethyl amino ethyl (meth)acrylate, diethyl amino ethyl (meth)acrylate, 7-amino-3,7-dimethyloctyl (meth)acrylate, N,N-diethyl (meth)acrylamide and N,N-dimethyl amino propyl (meth) acrylamide.

Examples of a commercially available product of the monofunctional (meth)acrylic compound include, but are not limited to, Aronix M101, M102, M110, M111, M113, M117, M5700, TO-1317, M120, M150 and M156 (all manufactured by Toagosei Co., Ltd.), MEDOL10, MIBDOL10, CHDOL10, MMDOL30, MEDOL30, MIBDOL30, CHDOL30, LA, IBXA, 2-MTA, HPA, Viscoat #150, #155, #158, #190, #192, #193, #220, #2000, #2100 and #2150 (all manufactured by Osaka Organic Chemical Industry Ltd.), Light acrylate BO-A, EC-A, DMP-A, THF-A, HOP-A, HOA-MPE, HOA-MPL, PO-A, P-200A, NP-4EA and NP-BEA, and Epoxy ester M-600A (all manufactured by Kyoeisha Chemical Co., Ltd.), KAYARAD TC110S, R-564 and R-128H (all manufactured by Nippon Kayaku Co., Ltd.), NK ester AMP-10G and AMP-20G (all manufactured by Shin-Nakamura Chemical Co., Ltd.), FA-511A, 512A and 513A (all manufactured by Hitachi Chemical Co., Ltd.), PHE, CEA, PHE-2, PHE-4, BR-31, BR-31M and BR-32 (all manufactured by Dai-Ichi Kogyo Seiyaku Co., Ltd.), VP (manufactured by BASF SE) and ACMO, DMAA and DMAPAA (all manufactured by Kohjin Holdings Co., Ltd.).

Examples of a polyfunctional (meth)acrylic compound having two or more acryloyl or methacryloyl groups include, but are not limited to, trimethylolpropane di(meth)acrylate, trimethylolpropane tri(meth)acrylate, EO-modified trimethylolpropane tri(meth)acrylate, PO-modified trimethylolpropane tri(meth)acrylate, EO,PO-modified trimethylolpropane tri(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, tris(2-hydroxyethyl)isocyanurate tri(meth)acrylate, tris(acryloyloxy) isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane and EO,PO-modified 2,2-bis(4-((meth)acryloxy)phenyl)propane.

Examples of a commercially available product of the polyfunctional (meth)acrylic compound include, but are not limited to, Upimer UV SA1002 and SA2007 (both manufactured by Mitsubishi Chemical Corporation), Viscoat #195, #230, #215, #260, #335HP, #295, #300, #360, #700, GPT and 3PA (all manufactured by Osaka Organic Chemical Industry Ltd.), Light acrylate 4EG-A, 9EG-A, NP-A, DCP-A, BP-4EA, BP-4PA, TMP-A, PE-3A, PE-4A and DPE-6A (all manufactured by Kyoeisha Chemical Co., Ltd.), KAYARAD PET-30, TMPTA, R-604, DPHA, DPCA-20, -30, -60 and -120, HX-620, D-310 and D-330 (all manufactured by Nippon Kayaku Co., Ltd.), Aronix M208, M210, M215, M220, M240, M305, M309, M310, M315, M325 and M400 (all manufactured by Toagosei Co., Ltd.) and Ripoxy VR-77, VR-60 and VR-90 (all manufactured by Showa Highpolymer Co., Ltd.).

One of the aforementioned radical polymerizable monomers can be singly used or two or more of the radical polymerizable monomers can be used in combination.

In the aforementioned compounds, (meth)acrylate means a combination of acrylate and methacrylate sharing an ester portion, and a (meth)acryloyl group means a combination of an acryloyl group and a methacryloyl group. Besides, EO stands for ethylene oxide, and an EO-modified compound means a compound having a block structure of an ethylene oxide group. Furthermore, PO stands for propylene oxide, and a PO-modified compound means a compound having a block structure of a propylene oxide group.

### (Cation Polymerizable Monomer)

The cation polymerizable monomer can be a compound having one or more vinyl ether groups, epoxy groups or oxetanyl groups.

Examples of a compound having one vinyl ether group include, but are not limited to, methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methyl cyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethyl cyclohexylmethyl vinyl ether, diethylene glycol mono vinyl ether, polyethylene glycol vinyl ether, chloroethyl vinyl ether, chlorobutyl vinyl ether, chloroethoxyethyl vinyl ether, phenylethyl vinyl ether and phenoxypolyethylene glycol vinyl ether.

Examples of a compound having two or more vinyl ether groups include, but are not limited to, divinyl ethers such as ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ether and bisphenol F alkylene oxide divinyl ether; and polyfunctional vinyl ethers such as trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, ethylene oxide-added trimethylolpropane trivinyl ether, propylene oxide-added trimethylolpropane trivinyl ether, ethylene oxide-added ditrimethylolpropane tetravinyl ether, propylene oxide-added ditrimethylolpropane tetravinyl ether, ethylene oxide-added pentaerythritol tetravinyl ether, propylene oxide-added pentaerythritol tetravinyl ether, ethylene oxide-added dipentaerythritol hexavinyl ether and propylene oxide-added dipentaerythritol hexavinyl ether.

Examples of a compound having one epoxy group include, but are not limited to, phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxy methylcyclohexene oxide, 3-acryloyloxy methylcyclohexene oxide and 3-vinylcyclohexene oxide.

Examples of a compound having two or more epoxy groups include, but are not limited to, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, an epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexane carboxylate, 2-(3,4-epoxycyclohexyl-5,5-spiro-3,4-epoxy)cyclohexane-meta-dioxane, bis(3,4-epoxycyclohexylmethyl)adipate, vinyl cyclohexene oxide, 4-vinylepoxycyclohexane, bis(3,4-epoxy-6-methylcyclohexylmethyl)adipate, 3,4-epoxy-6-methylcyclohexyl-3′,4′-epoxy-6′-methylcyclohexane carboxylate, methylene bis(3,4-epoxycyclohexane), dicyclopentadiene diepoxide, di(3,4-epoxycyclohexylmethyl)ether of ethylene glycol, ethylene bis(3,4-epoxycyclohexane carboxylate), dioctyl epoxyhexahydrophthalate, di-2-ethylhexyl epoxyhexahydrophthalate, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers, 1,1,3-tetradecadiene dioxide, limonene dioxide, 1,2,7,8-diepoxyoctane and 1,2,5,6-diepoxycyclooctane.

Examples of a compound having one oxetanyl group include, but are not limited to, 3-ethyl-3-hydroxymethyl oxetane, 3-(meth)acryloxymethyl-3-ethyl oxetane, (3-ethyl-3-oxetanylmethoxy)methyl benzene, 4-fluoro-[1-(3-ethyl-3-oxetanylmethoxy)methyl] benzene, 4-methoxy-[1-(3-ethyl-3-oxetanylmethoxy)methyl] benzene, [1-(3-ethyl-3-oxetanylmethoxy)ethyl]phenyl ether, isobutoxymethyl (3-ethyl-3-oxetanylmethyl)ether, isobornyloxyethyl (3-ethyl-3-oxetanylmethyl)ether, isobornyl (3-ethyl-3-oxetanylmethyl)ether, 2-ethylhexyl (3-ethyl-3-oxetanylmethyl)ether, ethyl diethylene glycol (3-ethyl-3-oxetanylmethyl)ether, dicyclopentadiene (3-ethyl-3-oxetanylmethyl)ether, dicyclopentenyloxyethyl (3-ethyl-3-oxetanylmethyl)ether, dicyclopentenyl (3-ethyl-3-oxetanylmethyl)ether, tetrahydrofurfuryl (3-ethyl-3-oxetanylmethyl)ether, tetrabromophenyl (3-ethyl-3-oxetanylmethyl)ether, 2-tetrabromophenoxyethyl (3-ethyl-3-oxetanylmethyl)ether, tribromophenyl (3-ethyl-3-oxetanylmethyl)ether, 2-tribromophenoxyethyl (3-ethyl-3-oxetanylmethyl)ether, 2-hydroxyethyl (3-ethyl-3-oxetanylmethyl)ether, 2-hydroxypropyl (3-ethyl-3-oxetanylmethyl)ether, butoxyethyl (3-ethyl-3-oxetanylmethyl)ether, pentachlorophenyl (3-ethyl-3-oxetanylmethyl)ether, pentabromophenyl (3-ethyl-3-oxetanylmethyl)ether and bornyl (3-ethyl-3-oxetanylmethyl)ether.

Examples of a compound having two or more oxetanyl groups include, but are not limited to, polyfunctional oxetanes such as 3,7-bis(3-oxetanyl)-5-oxa-nonane, 3,3′-(1,3-(2-methylenyl)propanediylbis(oxymethylene))bis-(3-ethyloxetane), 1,4-bis[(3-ethyl-3-oxetanylmethoxy)methyl] benzene, 1,2-bis[(3-ethyl-3-oxetanylmethoxy)methyl]ethane, 1,3-bis[(3-ethyl-3-oxetanylmethoxy)methyl] propane, ethylene glycol bis(3-ethyl-3-oxetanylmethyl)ether, dicyclopentenylbis(3-ethyl-3-oxetanylmethyl)ether, triethylene glycolbis(3-ethyl-3-oxetanylmethyl)ether, tetraethylene glycolbis(3-ethyl-3-oxetanylmethyl)ether, tricyclodecanediyldimethylene(3-ethyl-3-oxetanylmethyl)ether, trimethylolpropanetris(3-ethyl-3-oxetanylmethyl)ether, 1,4-bis(3-ethyl-3-oxetanylmethoxy) butane, 1,6-bis(3-ethyl-3-oxetanylmethoxy) hexane, pentaerythritoltris(3-ethyl-3-oxetanylmethyl)ether, pentaerythritoltetrakis(3-ethyl-3-oxetanylmethyl)ether, polyethylene glycolbis(3-ethyl-3-oxetanylmethyl)ether, dipentaerythritolhexakis(3-ethyl-3-oxetanylmethyl)ether, dipentaerythritolpentakis(3-ethyl-3-oxetanylmethyl)ether, dipentaerythritoltetrakis(3-ethyl-3-oxetanylmethyl)ether, caprolactone-modified dipentaerythritolhexakis(3-ethyl-3-oxetanylmethyl)ether, caprolactone-modified dipentaerythritolpentakis(3-ethyl-3-oxetanylmethyl)ether, ditrimethylolpropanetetrakis(3-ethyl-3-oxetanylmethyl)ether, EO-modified bisphenol A bis(3-ethyl-3-oxetanylmethyl)ether, PO-modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether and EO-modified bisphenol F (3-ethyl-3-oxetanylmethyl)ether.

One of the aforementioned cation polymerizable monomers may be singly used or two or more of the cation polymerizable monomers may be used in combination.

### (1-2) Curing Aid

In the present invention, a curing aid is a compound that produces a component for aiding the curing (polymerization or crosslinkage) of the photocurable component when the photocurable composition is irradiated with light. More specifically, the curing aid is a compound that produces radicals, cations or anions working as chemical species for starting the polymerization/crosslinkage of a polymerizable monomer used as the photocurable component when irradiated with light, and is a compound designated also as a photopolymerization initiator.

If a radical polymerizable monomer is used as the photocurable component (the polymerizable monomer), the curing aid is a radical generating agent. On the other hand, if a cation polymerizable monomer is used as the photocurable component (the polymerizable monomer), the curing aid is a photo-acid generating agent.

### (Radical Generating Agent)

A radical generating agent for generating radicals by light irradiation is a compound for starting radical polymerization by producing radicals through a chemical reaction caused by irradiation with radiation such as infrared rays, visible rays, ultraviolet rays, far ultraviolet rays, X-rays and charged particle beams of electron rays or the like.

Examples of a compound corresponding to the radical generating agent include, but are not limited to, 2,4,5-triarylimidazole dimers that may have a substituent, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer and a 2-(o- or p-methoxyphenyl)-4,5-diphenylimidazole dimer; benzophenone derivatives such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 4-chlorobenzophenone, 4,4′-dimethoxybenzophenone and 4,4′-diaminobenzophenone; aromatic ketone derivatives such as 2-benzyl-2-dimethylamino-1-(4-morpholinophenyl)-butanone-1,2-methyl-1-[4-(methylthio)phenyl]-2-morpholino-propanone-1-one; quinones such as 2-ethylanthraquinone, phenanthrene quinone, 2-t-butylanthraquinone, octamethylanthraquinone, 1,2-benzanthraquinone, 2,3-benzanthraquinone, 2-phenylanthraquinone, 2,3-dipheylanthraquinone, 1-chloroanthraquinone, 2-methylanthraquinone, 1,4-naphthoquinone, 9,10-phenanthraquinone, 2-methyl-1,4-naphthoquinone and 2,3-dimethylanthraquinone; benzoin ether derivatives such as benzoin methyl ether, benzoin ethyl ether and benzoin phenyl ether; benzoin derivatives such as benzoin, methyl benzoin, ethyl benzoin and propyl benzoin; benzyl derivatives such as benzyl dimethyl ketal; acridine derivatives such as 9-phenyl acridine and 1,7-bis(9,9′-acridinyl)heptane; phenyl glycine derivatives such as N-phenylglycine; acetophenone derivatives such as acetophenone, 3-methyl acetophenone, acetophenone benzyl ketal, 1-hydroxycyclohexyl phenyl ketone and 2,2-dimethoxy-2-phenyl acetophenone; thioxanthone derivatives such as thioxanthone, diethyl thioxanthone, 2-isopropyl thioxanthone and 2-chlorothioxanthone; xanthone, fluorenone, benzaldehyde, fluorene, anthraquinone, triphenylamine, carbazole, 1-(4-isopropylphenyl)-2-hydroxy-2-methylpropane-1-on, 2-hydroxy-2-methyl-1-phenylpropane-1-on, 2,4,6-trimethylbenzoyl diphenylphosphine oxide and bis-(2,6-dimethoxybenzoyl)-2,4,4-trimethylpentyl phosphine oxide.

One of the radical generating agents may be singly used or two or more of the radical generating agents may be used in combination.

Examples of a commercially available product of the radical generating agent include, but are not limited to, Irgacure 184, 369, 651, 500, 819, 907, 784 and 2959, CGI-1700, -1750 and -1850, CG24-61, and Darocur 1116 and 1173 (all manufactured by Ciba Japan K.K.), Lucirin TPO, LR8893 and LR8970 (all manufactured by BASF SE) and Ebecryl P36 (manufactured by UCB).

### (Photo-Acid Generating Agent)

A photo-acid generating agent for generating cations such as hydrogen ions by light irradiation is a compound for starting cation polymerization by producing an acid (cation) through irradiation with radiation such as infrared rays, visible rays, ultraviolet rays, far ultraviolet rays, X-rays and charged particle beams of electron rays or the like. Examples of such a compound include, but are not limited to, an onium salt compound, a sulfone compound, a sulfonate compound, a sulfonimide compound and a diazomethane compound. In the present invention, the onium salt compound can be used.

Examples of the onium salt compound include iodonium salt, sulfonium salt, phosphonium salt, diazonium salt, ammonium salt and pyridinium salt. Specific examples of the onium salt compound include, but are not limited to, bis(4-t-butylphenyl)iodonium perfluoro-n-butane sulfonate, bis(4-t-butylphenyl)iodonium trifluoro methanesulfonate, bis(4-t-butylphenyl)iodonium 2-trifluoro methylbenzene sulfonate, bis(4-t-butylphenyl)iodonium pyrenesulfonate, bis(4-t-butylphenyl)iodonium n-dodecylbenzenesulfonate, bis(4-t-butylphenyl)iodonium p-toluenesulfonate, bis(4-t-butylphenyl)iodonium benzenesulfonate, bis(4-t-butylphenyl)iodonium 10-camphorsulfonate, bis(4-t-butylphenyl)iodonium n-octanesulfonate, diphenyliodonium perfluoro-n-butanesulfonate, diphenyliodonium trifluoro methanesulfonate, diphenyliodonium 2-trifluoro methylbenzene sulfonate, diphenyliodonium pyrenesulfonate, diphenyliodonium n-dodecyl benzenesulfonate, diphenyliodonium p-toluenesulfonate, diphenyliodnium benzenesulfonate, diphenyliodonium 10-camphorsulfonate, diphenyliodonium n-octanesulfonate, triphenylsulfonium perfluoro-n-butanesulfonate, triphenylsulfonium trifluoro methanesulfonate, triphenylsulfonium 2-trifluoromethylbenzenesulfonate, triphenylsulfonium pyrenesulfonate, triphenlsulfonium n-dodecylbenzenesulfonate, triphenylsulfonium p-toluenesulfonate, triphenylsulfonium benzenesulfonate, triphenylsulfonium 10-camphorsulfonate, triphenylsulfonium n-octanesulfonate, diphenyl(4-t-butylphenyl)sulfonium perfluoro-n-butanesulfonate, diphenyl(4-t-butylphenyl)sulfonium trifluoromethanesulfonate, diphenyl(4-t-butylphenyl)sulfonium 2-trifluoromethylbenzenesulfonate, diphenyl(4-t-butylphenyl)sulfonium pyrenesulfonate, diphenyl(4-t-butylphenyl)sulfonium n-dodecylbenzenesulfonate, diphenyl(4-t-butylphenyl)sulfonium p-toluenesulfonate, diphenyl(4-t-butylphenyl)sulfonium benzenesulfonate, diphenyl(4-t-butylphenyl)sulfonium 10-camphorsulfonate, diphenyl(4-t-butylphenyl)sulfonium n-octanesulfonate, tris(4-methoxyphenyl)sulfonium perfluoro-n-butanesulfonate, tris(4-methoxyphenyl)sulfonium trifluoromethanesulfonate, tris(4-methoxyphenyl)sulfonium 2-trifluoromethylbenzenesuflonate, tris(4-methoxyphenyl)sulfonium pyrenesulfonate, tris(4-methoxyphenyl)sulfonium n-dodecylbenzenesulfonate, tris(4-methoxyphenyl)sulfonium p-toluenesulfonate, tris(4-methoxyphenyl)sulfonium benzenesulfonate, tris(4-methoxyphenyl)sulfonium 10-camphorsulfonate and tris(4-methoxyphenyl)sulfonium n-octanesulfonate.

Examples of the sulfone compound include β-ketosulfone, β-sulfonylsulfone and α-diazo compounds of these. Specific examples of the sulfone compound include, but are not limited to, phenacylphenyl sulfone, mesityl phenacyl sulfone, bis(phenylsulfonyl)methane and 4-trisphenacyl sulfone.

Examples of the sulfonate compound include alkyl sulfonate, haloalkyl sulfonate, aryl sulfonate and iminosulfonate. Specific examples of the sulfonate compound include, but are not limited to, α-methylolbenzoin perfluoro-n-butane sulfonate, α-methylolbenzoin trifluoromethane sulfonate and α-methylolbenzoin 2-trifluoromethyl benzene sulfonate.

Specific examples of the sulfonimide compound include, but are not limited to, N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hept-5-en-2,3-dicarboxylmide, N-(trifluoromethylsulfonyloxy)-7-oxabicyclo[2.2.1]hept-5-en-2,3-dicarboxylmide, N-(trifluoromethylsulfonyloxy)bicyclo[2.2.1]heptane-5,6-oxy-2,3-dicarboxylmide, N-(trifluoromethylsulfonyloxy)naphthylimide, N-(10-camphorsulfonyloxy)succinimide, N-(10-camphorsulfonyloxy)phthalimide, N-(10-camphorsulfonyloxy)diphenylmaleimide, N-(10-camphorsulfonyloxy)bicyclo[2.2.1]hept-5-en-2,3-dicarboxylmide, N-(10-camphorsulfonyloxy)-7-oxabicyclo[2.2.1]hept-5-en-2,3-dicarboxylmide, N-(10-camphorsulfonyloxy)bicyclo[2.2.1]heptane-5,6-oxy-2,3-dicarboxylmide, N-(10-camphorsulfonyloxy)naphthylimide, N-(4-methylphenylsulfonyloxy)succinimide, N-(4-methylphenylsulfonyloxy)phthalimide, N-(4-methylphenylsulfonyloxy)diphenylmaleimide, N-(4-methylphenylsulfonyloxy)bicyclo[2.2.1]hept-5-en-2,3-dicarboxylmide, N-(4-methylphenylsulfonyloxy)-7-oxabicyclo[2.2.1]hept-5-en-2,3-dicarboxylmide, N-(4-methylphenylsulfonyloxy)bicyclo[2.2.1]heptane-5,6-oxy-2,3-dicarboxylmide, N-(4-methylphenylsulfonyloxy)naphthylimide, N-(2-trifluoromethylphenylsulfonyloxy)succinimide, N-(2-trifluoromethylphenylsulfonyloxy)phthalimide, N-(2-trifluoromethylphenylsulfonyloxy)diphenylmaleimide, N-(2-trifluoromethylphenylsulfonyloxy)bicyclo[2.2.1]hept-5-en-2,3-dicarboxylmide, N-(2-trifluoromethylphenylsulfonyloxy)-7-oxabicyclo[2.2.1]hept-5-en-2,3-dicarboxylmide, N-(2-trifluoromethylphenylsulfonyloxy)bicyclo[2.2.1]heptane-5,6-oxy-2,3-dicarboxylmide, N-(2-trifluoromethylphenylsulfonyloxy)naphthylimide, N-(4-fluorophenylsulfonyloxy)succinimide, N-(4-fluorophenyl)phthalimide, N-(4-fluorophenylsulfonyloxy)diphenylmaleimide, N-(4-fluorophenylsulfonyloxy)bicyclo[2.2.1]hept-5-en-2,3-dicarboxylmide, N-(4-fluorophenylsulfonyloxy)-7-oxabicyclo[2.2.1]hept-5-en-2,3-dicarboxylmide, N-(4-fluorophenylsulfonyloxy)bicyclo[2.2.1]heptane-5,6-oxy-2,3-dicarboxylmide and N-(4-fluorophenylsulfonyloxy)naphthylimide.

Specific examples of the diazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl p-toluenesulfonyl diazomethane, (cyclohexylsulfonyl)(1,1-dimethylethylsulfonyl)diazomethane and bis(1,1-dimethylethylsulfonyl)diazomethane.

Of the aforementioned photo-acid generating agents, the onium salt compound can be used. Besides, in the present invention, one of the aforementioned photo-acid generating agents may be singly used, or two or more of the photo-acid generating agents may be used in combination.

A blending ratio of the photopolymerization initiator used as the curing aid is 0.01% by weight or more and 10% by weight or less and preferably 0.1% by weight or more and 7% by weight or less of the total amount of the photocurable component (the polymerizable monomer(s)) included in the photocurable composition of the present invention. When the blending ratio is smaller than 0.01% by weight, a curing rate may be lowered so as to degrade reaction efficiency. On the other hand, when the blending ratio exceeds 10% by weight, the photocured product to be prepared may be degraded in mechanical characteristics thereof.

### (1-3) Surface Active Agent

The surface active agent included in the photocurable composition is the same material/compound unevenly distributed at surface of the photocured product.

If a mold having a surface active agent applied onto a surface thereof is used, the surface active agent having been applied to the surface of the mold may be gradually detached while the imprint is repeatedly performed. On the other hand, if a surface active agent is included in the photocurable composition, the surface active agent is always supplied to the mold and the photocured product while the imprint is repeatedly performed, and hence, this method is superior in repetition durability. Accordingly, in the present invention, the surface active agent can be included in the photocurable composition.

### (1-4) Additive Component

The photocurable composition of the present invention may include, in addition to the photocurable component (the polymerizable monomer), the curing aid (the photopolymerization initiator) and the surface active agent, an additive component according to various purposes as long as the effects of the present invention are not harmed. Here, an additive component specifically means a component such as a sensitizing agent, an antioxidant, a solvent or a polymer component. Specific examples of the additive component will now be described.

### (Sensitizing Agent)

For the purpose of accelerating the polymerization reaction and improving a degree of conversion of the reaction, the photocurable composition of the present invention may include a sensitizing agent. A hydrogen donor or a sensitizing dye may be added as a sensitizing agent.

A hydrogen donor is a compound that generates radicals showing higher reactivity through a reaction with the initiation radicals generated from the photopolymerization initiator (a component B) or radicals present at polymer chain ends. A hydrogen donor can be added when a photo radical generating agent is used as the photopolymerization initiator (the component B).

As a hydrogen donor, commonly used known compounds may be used. Specific examples include, but are not limited to, amine compounds such as N-butylamine, di-n-butylamine, tri-n-butylphosphine, allylthiourea, s-benzyl isothiuronium-p-toluenesulfinate, triethylamine, diethylaminoethyl methacrylate, triethylene tetramine, 4,4′-bis(dialkylamino)benzophenone, ethyl N,N-dimethylamino benzoate, isoamyl N,N-dimethylamino benzoate, pentyl-4-dimethylamino benzoate, triethanolamine and N-phenylglycine; and mercapto compounds such as 2-mercapto-N-phenyl benzoimidazole and mercaptopropionate.

A sensitizing dye is a compound that is excited through absorption of light of a specific wavelength for inducing interaction with a curing aid (a photopolymerization initiator). The interaction herein specifically includes energy transfer, electron transfer or the like from the sensitizing dye placed in an excited state.

As a sensitizing dye, commonly used known compounds may be used. Specific examples include, but are not limited to, anthracene derivatives, anthraquinone derivatives, pyrene derivatives, perylene derivatives, carbazole derivatives, benzophenone derivatives, thioxanthone derivatives, xanthone derivatives, thioxanthone derivatives, cumarin derivatives, phenothiazine derivatives, camphorquinone derivatives, acridine dyes, thiopyrylium salt dyes, merocyanine dyes, quinoline dyes, styrylquinoline dyes, ketocumarin dyes, thioxanthene dyes, xanthene dyes, oxonol dyes, cyanine dyes, rhodamine dyes and pyrylium salt dyes.

One of these sensitizing agents may be singly used or two or more of the sensitizing agents may be used in the form of a mixture. Furthermore, a content percentage of the sensitizing agent in the photocurable composition of the present invention is preferably 0 to 20% by weight, more preferably 0.1 to 5.0% by weight and still more preferably 0.2 to 2.0% by weight based on the total amount of the photocurable component (the polymerizable monomer(s)). When the content of the sensitizing agent is 0.1% by weight or more, the effect of the sensitizing agent can be more effectively shown. Besides, when the content of the sensitizing agent is 5% by weight or less, the molecular weight of the photocured product can be sufficiently increased and insufficient dissolution and degradation of storage stability can be suppressed.

### (Method for Blending Respective Components)

The photocurable composition of the present invention can be prepared by mixing the aforementioned respective components. Here, a temperature condition for mixing and dissolving the respective components of the photocurable composition is generally set to a range of 0° C. to 100° C. Incidentally, a solvent may be used in preparing the photocurable composition. A solvent to be used in preparing the photocurable composition is not especially limited as long as the solvent does not cause phase separation from a polymerizable polymer.

### (Viscosity of Composition)

As for the viscosity of the photocurable composition of the present invention, the viscosity at 23° C. of a mixture of the components excluding a solvent is preferably 1 cP to 100 cP, more preferably 5 cP to 50 cP and still more preferably 6 cP to 20 cP. When the viscosity of the photocurable composition is higher than 100 cP, it may take long time to fill recesses of a fine pattern on a mold with the composition in bringing the photocurable composition into contact with the mold or a pattern failure derived from insufficient filling may be caused. On the other hand, when the viscosity is lower than 1 cP, it is apprehended that application unevenness may be caused in applying the photocurable composition or that the photocurable composition may flow out from an end of the mold in bringing the photocurable composition into contact with the mold.

### (Surface Tension of Composition)

As for the surface tension of the photocurable composition of the present invention, the surface tension at 23° C. of the mixture of the components excluding a solvent is preferably 5 mN/m to 70 mN/m, more preferably 7 mN/m to 35 mN/m and still more preferably 10 mN/m to 32 mN/m. When the surface tension is lower than 5 mN/m, it takes long time to fill recesses of a fine pattern on a mold with the composition in bringing the photocurable composition into contact with the mold. On the other hand, when the surface tension is higher than 70 mN/m, surface smoothness is lowered.

### (Impurities)

Impurities are desired to be removed from the photocurable composition of the present invention as much as possible. For example, in order to prevent occurrence of a pattern failure of the photocured product caused by particles mixed in the photocurable composition, after mixing the respective components of the photocurable composition, the mixture is preferably filtered by a filter with a pore size of 0.001 μm to 5.0 μm. In employing the filtration by a filter, the filtration is performed more preferably in a plurality of stages or repeated by a plurality of times. Alternatively, a filtered solution may be filtered again. The filter to be used for the filtration can be any of polyethylene resin, polypropylene resin, fluororesin and nylon resin filters, but the filter is not especially limited.

Incidentally, if the photocurable composition of the present invention is used for manufacturing a semiconductor integrated circuit, contamination with metal impurities of the composition is preferably avoided as much as possible so that the operation of a resulting product may not be impeded. Accordingly, in the photocurable composition of the present invention, a concentration of metal impurities is suppressed to preferably 10 ppm or less and more preferably 100 ppb or less.

### (1-5) Specific Application Method

Next, a specific method of conducting this step (applying step) will be described. In this step, the photocurable composition 1 is applied onto the substrate 2 so as to form a coat film. The photocurable composition 1 provided on the substrate 2 in the form of a coat film in this step is designated also as a shape-transferred layer.

A substrate to be processed corresponding to the substrate 2 is generally, but not limited to, a silicon wafer. Apart from a silicon wafer, any of substrates known as semiconductor device substrates of aluminum, titanium-tungsten alloy, aluminum-silicon alloy, aluminum-copper-silicon alloy, silicon oxide, silicon nitride or the like can be arbitrarily selected for use. Incidentally, as the substrate to be used (the substrate to be processed), a substrate improved in adhesion to the photocurable composition by a surface treatment, such as a silane coupling treatment, a silazane treatment or formation of an organic thin film, may be used.

As a method for applying the photocurable composition of the present invention onto the substrate to be processed, for example, an ink jet method, a dip coating method, an air knife coating method, a curtain coating method, a wire bar coating method, a gravure coating method, an extrusion coating method, a spin coating method or a slit-scan method can be employed. It is noted that the thickness of the shape-transferred layer (the coat film) depends upon the use application and is, for example, 0.01 μm to 100.0 μm.

### (2) Contact Step (FIGS. 1B1, 1B2)

Next, the step of bringing a mold into contact with the coat film of the photocurable composition 1 formed in the previous step (the applying step) (contact step, FIGS. 1B1 and 1B2) is conducted. Since a mold 3 can be likened to a seal, this step is designated also as a sealing step. In this step, when the mold 3 is brought into contact with the photocurable composition 1 (the shape-transferred layer) (FIG. 1B1), (a part of) a coat film 10 is filled in recesses of a fine pattern formed on the mold 3 (FIG. 1B2).

The mold 3 used in the contact step needs to be made of an optically transparent material in consideration of the next step (light irradiation step). Specific examples of the material for the mold 3 include glass, quartz, optically transparent resins such as PMMA and polycarbonate resin, transparent deposited metal films, flexible films of polydimethylsiloxane and the like, photocured films and metal films. If an optically transparent resin is used as the material for the mold 3, however, it is necessary to select a resin not dissolved in the solvent included in the photocurable composition 1.

The mold 3 used in the production method for the photocured product of the present invention may be subjected to a surface treatment for improving a detaching property between the photocurable composition 1 and the surface of the mold 3. As a method of the surface treatment, a treatment with, for example, a silicone-based or fluorine-based silane coupling agent may be performed, and specifically, a commercially available coating-type mold releasing agent such as Optool DSX manufactured by Daikin Industries, Ltd. can be suitably used.

In the contact step, a pressure applied to the photocurable composition 1 in bringing the mold 3 into contact with the photocurable composition 1 as illustrated in FIG. 1B1 is not especially limited but is generally 0.1 MPa to 100 MPa. Particularly, the pressure is preferably 0.1 MPa to 50 MPa, more preferably 0.1 MPa to 30 MPa and still more preferably 0.1 MPa to 20 MPa. Furthermore, time for bringing the mold 3 into contact with the shape-transferred layer 1 in the contact step is not especially limited but is generally 1 second to 600 seconds, preferably 1 second to 300 seconds, more preferably 1 second to 180 seconds and particularly preferably 1 second to 120 seconds.

Moreover, the contact step can be performed under any condition of an atmospheric environment, a reduced pressure environment and an inert gas environment. A reduced pressure environment and an inert gas environment are preferred because the influence of oxygen and moisture on the photocuring reaction can be prevented under these environments. If the contact step is conducted under an inert gas environment, specific examples of an inert gas to be used include nitrogen, carbon dioxide, helium, argon, various chlorofluorocarbon gases and mixed gases of these. If this step (contact step) is conducted under an environment of a specific gas including an atmospheric environment, the pressure of the gas can be 0.0001 to 10 atmospheres.

### (3) Light Irradiation Step (FIG. 1C)

Next, the coat film 10 is irradiated with light through the mold 3 (FIG. 1C). In this step, the coat film 10 is cured by irradiation light and formed into the photocured product 11.

At this point, the light used for irradiating the photocurable composition 1 included in the coat film 10 is selected according to the sensitivity wavelength of the photocurable composition 1. Specifically, the light can be appropriately selected from ultraviolet rays of a wavelength of approximately 150 nm to 400 nm, X-rays, electron rays and the like. Many of commercially available curing aids (photopolymerization initiators) are compounds having sensitivity to ultraviolet rays. Therefore, ultraviolet rays are particularly preferably employed as the light (irradiation light 4) used for irradiating the photocurable composition 1. Examples of a light source of ultraviolet rays include a high pressure mercury vapor lamp, an extra-high pressure mercury vapor lamp, a low pressure mercury vapor lamp, a Deep-UV lamp, a carbon arc lamp, a chemical lamp, a metal halide lamp, a xenon lamp, a KrF excimer laser, an ArF excimer laser and F₂ excimer laser, of which an extra-high pressure mercury vapor lamp is particularly preferably used. Besides, the number of light sources to be used may be one or plural. Furthermore, the light irradiation may be performed on the whole of or merely a part of the surface of the photocurable composition 1.

Moreover, if the shape-transferred layer is also thermally cured, heat curing can be further conducted. If the heat curing is conducted, the heating atmosphere, the heating temperature and the like are not especially limited. For example, the photocurable composition 1 can be heated under an inert atmosphere or a reduced pressure at a temperature in the range of 40° C. to 200° C. Besides, for heating the shape-transferred layer 1, a hot plate, an oven, a furnace or the like can be used.

### (4) Mold Releasing Step (FIG. 1D)

Next, a step of forming a cured film having a prescribed pattern on the substrate 2 by removing the mold 3 from the photocured product 11 (mold releasing step, FIG. 1D) is conducted. In this step (mold releasing step), the mold 3 is detached from the photocured product 11, and an inverted pattern of the fine pattern formed on the mold 3 in the previous step (the light irradiation step) is obtained as a pattern of the photocured product 11.

A method for detaching the mold 3 off from the photocured product 11 is not especially limited unless a part of the photocured product 11 is physically damaged during the detaching, and various conditions and the like are not especially limited. For example, with the substrate to be processed (the substrate 2) fixed, the mold 3 may be moved to be away from the substrate to be processed, or with the mold 3 fixed, the substrate to be processed may be moved to be away from the mold, or both the mold and the substrate may be pulled in the opposite directions to be detached from each other.

Alternatively, a method using a coating-type mold releasing agent for detaching the mold 3 off from the photocured product 11 can be employed. In order to peel the mold 3 off from the photocured product 11 by using a coating-type mold releasing agent, a step of forming a coating-type mold releasing agent layer on the surface of the mold having a desired pattern is conducted before the contact step.

If a coating-type mold releasing agent is used, the kind of mold releasing agent is not especially limited, and examples of such a mold releasing agent include silicon mold releasing agents, fluorine mold releasing agents, polyethylene mold releasing agents, polypropylene mold releasing agents, paraffin mold releasing agents, montan mold releasing agents and carnauba mold releasing agents. One of such mold releasing agents may be singly used, or two or more of the agents may be used in combination. Of these mold releasing agents, a fluorine mold releasing agent is particularly preferably used.

### (5) Etching Step (FIG. 1E)

Although the cured film obtained by performing the mold releasing step has a specific pattern shape, a part of the film may be present as a remaining film in a region other than a region where the pattern shape should be formed. Therefore, a step of removing a remaining photocured film (remaining film) in a region of the formed pattern shape where the photocured product should be removed (etching step, FIG. 1E) is conducted.

As a method for removing the remaining film, for example, a film portion remaining in recesses of the photocured product 11 (remaining film) is removed by etching, so as to expose the surface of the substrate 2 in the recesses of the pattern.

In the case where the etching is employed, a specific method for the etching is not especially limited, and any of conventionally known methods such as dry etching may be performed. For the dry etching, a conventionally known dry etching apparatus can be used. A source gas to be used in the dry etching may be appropriately selected according to the elemental composition of a film to be etched, and any of gases including an oxygen atom, such as O₂, CO and CO₂, inert gases such as He, N₂ and Ar, chlorine gases such as Cl₂ and BCl₃, gases of H₂ and NH₃ and the like can be used. Incidentally, these gases may be used in the form of a mixture.

Through the production process including the steps (1) to (5), the photocured product 11 having a desired protruding and recessed pattern shape (a pattern shape due to the shape of protrusion and recession on the mold 3) can be obtained. If this photocured product 11 is used for further processing the substrate 2, a substrate processing step described below may be further performed.

On the other hand, the thus obtained photocured product 11 may be used as an optical element (including a case where the photocured product is used as one member of an optical element). In such a case, an optical component at least including the substrate 2 and the photocured product 11 disposed on the substrate 2 can be provided.

### (6) Substrate Processing Step (FIG. 1F)

The photocured product 11 having a desired protruding and recessed pattern shape obtained by the production method of the present invention may be used as, for example, an interlayer insulating film included in an electronic component typified by a semiconductor device such as an LSI, a system LSI, a DRAM, an SDRAM, an RDRAM and a D-RDRAM. On the other hand, the photocured product 11 may be used also as a resist film in the production of a semiconductor device.

If the photocured product 11 is used as a resist film, specifically, a part of the substrate whose surface is exposed in the etching step (a region corresponding to a reference numeral 20) is subjected to etching, ion implantation or the like as illustrated in FIG. 1F. At this point, the photocured product 11 functions as a mask. In this manner, a circuit 20 based on the pattern shape of the photocured product 11 can be formed on the substrate 2. Thus, a circuit board used in a semiconductor device or the like can be produced. Incidentally, this circuit board is provided with electronic members, so as to produce an electronic component.

If a circuit board or an electronic component is to be prepared, the pattern of the photocured product may be removed from the processed substrate ultimately or can be allowed to remain thereon as a member of a resulting element.

### EXAMPLES

The present invention will now be described in more details with reference to Examples, but the present invention is not limited to the Examples described below. In the following description, “part(s)” and “%” mean “part(s) by weight” and “% by weight” unless otherwise mentioned.

### Synthesis Example 1

### Synthesis of Surface Active Agent (C-1)

A 300 mL reactor whose inside system had been set to a nitrogen atmosphere was charged with the following reagents and solvent:

Hexaethylene glycol (PEG6): 26.5 g (93.9 mmol, 1.0 eq)
Carbon tetrachloride (CCl₄): 36.1 g (235 mmol, 2.5 eq.)

### Tetrahydrofuran (THF): 106 mL

Next, the reaction solution was cooled to −30° C. Then, a THF solution prepared by mixing 24 mL of THF and 15.3 g (93.9 mmol, 1.0 eq) of dimethyl amino phosphine was slowly added to the reaction solution over 2 hours, and the resulting solution was stirred for 30 minutes at that temperature (−30° C.). After removing the cooling bath, the reaction solution was stirred at room temperature for 2 hours. Then, 250 mL of city water was added to the thus obtained pale yellow suspension, so as to divide the resultant into two layers (of a CCl₄ layer and an aqueous layer). The aqueous layer was washed twice with 150 mL of isopropyl ether (IPE). To the resulting aqueous layer, a suspension obtained by suspending 34.5 g (188 mmol, 2.0 eq.) of potassium hexafluorophosphate (KPF₆) in 250 mL of city water was added, and the aqueous layer was sufficiently stirred therein. Next, the resulting aqueous layer was subjected to three solvent extraction operations with 200 mL of dichloromethane. Subsequently, after collecting organic layers (of a CCl₄ layer and a dichloromethane layer), the organic layers were washed with 400 mL of city water and 300 mL of saturated brine in this order, followed by drying over anhydrous magnesium sulfate. Thereafter, the organic layers were concentrated, so as to obtain 53 g of a compound (C-1-a) as a pale brown liquid.

Next, a 500 mL reactor was charged with the following reagent and solvent:

1H,1H-perfluoro-1-heptanol: 34.2 g (97.7 mmol, 1.2 eq.)

### THF: 120 mL

To the reaction solution, 3.9 g (97.7 mmol, 1.2 eq.) of NaH (60%) was slowly added carefully so as not to foam. Next, the resulting reaction solution was heated to 50° C. and stirred for 1 hour at that temperature (50° C.) The solvent included in the reaction solution was distilled off under reduced pressure, and to the thus obtained residue, a dioxane solution prepared by mixing 600 mL of anhydrous dioxane and 53 g of the compound (C-1-a) was added. Next, the reaction solution was heated to 60° C. and stirred for 48 hours at that temperature (60° C.). Thereafter, 300 mL of city water and 300 mL of ethyl acetate were added to a residue obtained by concentrating the reaction solution, followed by a separating operation for dividing the resultant into two layers. The thus obtained aqueous layer was subjected to two solvent extraction operations with 200 mL of ethyl acetate. Then, after collecting organic layers and washing the organic layers with 400 mL of city water and 400 mL of saturated brine successively, the resulting organic layers were dried over anhydrous magnesium sulfate. Next, the organic layers were concentrated under reduced pressure, so as to give 59.1 g of a brown liquid. This liquid was purified by column chromatography (filler: SiO₂ (1.2 kg), eluting solvent: ethyl acetate alone and changed afterward to ethyl acetate/methanol=10/1). The resultant was purified again by another column chromatography (filler: SiO₂ (400 g), eluting solvent: chloroform/methanol=15/1 and changed afterward to 10/1), and the thus purified product was dried under high vacuum. In this manner, a surface active agent (C-1) (F(CF₂)₆CH₂(OCH₂CH₂)₆OH) was obtained as a colorless liquid in an amount of 19.2 g (31.2 mmol, yield: 33%).

### Synthesis Example 2

### Synthesis of Surface Active Agent (C-2)

A 100 mL reactor whose inside system had been set to a nitrogen atmosphere was charged with the following reagents and solvent:

Hexapropylene glycol (P400): 20 g (50 mmol, 1.0 eq)
Carbon tetrachloride (CCl₄): 19.2 g (125 mmol, 2.5 eq.)

### Tetrahydrofuran (THF): 100 mL

Next, the reaction solution was cooled to −30° C. Then, a THF solution obtained by mixing 30 mL of THF and 8.16 g (10 mmol, 1.0 eq) of dimethyl amino phosphine was slowly added to the reaction solution over 2 hours, and the resulting solution was stirred for 30 minutes at that temperature (−30° C.). After removing the cooling bath, the reaction solution was stirred at room temperature for 2 hours. Then, city water (350 mL) was added to the thus obtained pale yellow suspension, so as to divide the resultant into two layers (of a CCl₄ layer and an aqueous layer) by a separating operation. The obtained aqueous layer was washed twice with 150 mL of isopropyl ether (IPE). To the resulting aqueous layer, a suspension prepared by mixing and suspending 18.4 g (100 mmol, 2.0 eq.) of potassium hexafluorophosphate (KPF₆) in 250 mL of city water was added, and the aqueous layer was sufficiently stirred therein. Next, the resulting solution was subjected to three solvent extraction operations with 150 mL of dichloromethane. Subsequently, after collecting organic layers (of a CCl₄ layer and a dichloromethane layer), the organic layers were washed with 500 mL of city water and 300 mL of saturated brine successively, followed by drying over anhydrous magnesium sulfate. Thereafter, the organic layers were concentrated under reduced pressure, so as to obtain 31 g of a compound (C-2-a) as a pale brown liquid.

Next, a 500 mL reactor was charged with the following reagent and solvent:

1H,1H-perfluoro-1-heptanol: 21 g (60 mmol, 1.2 eq.)

### THF: 120 mL

To the reaction solution, 3.9 g (97.7 mmol, 1.2 eq.) of NaH (60%) was slowly added carefully so as not to foam. Next, the resulting reaction solution was heated to 40° C. and stirred for 1 hour at that temperature (40° C.) To a residue obtained by distilling off the solvent under reduced pressure, a dioxane solution prepared by mixing 350 mL of anhydrous dioxane and 53 g of the compound (C-2-a) was added. Next, the reaction solution was heated to 60° C. and stirred for 24 hours at that temperature (60° C.). Thereafter, 200 mL of city water and 200 mL of ethyl acetate were added to a residue obtained by concentrating the reaction solution, followed by a separating operation for dividing the resultant into two layers. The thus obtained aqueous layer was washed twice with 150 mL of ethyl acetate, and then organic layers were collected. Then, after washing the organic layers with 500 mL of city water and 500 mL of saturated brine successively, the resulting organic layers were dried over anhydrous magnesium sulfate. Next, the organic layers were concentrated, so as to give 29 g of a brown liquid. This brown liquid was purified by column chromatography (filler: SiO₂ (0.9 kg), eluting solvent: ethyl acetate/hexane=2/1 and changed afterward to ethyl acetate alone). The resultant was purified again by another column chromatography (filler: SiO₂ (300 g), eluting solvent: chloroform/methanol=20/1 and changed afterward to 10/1), and the thus purified product was dried under high vacuum. In this manner, a surface active agent (C-2) (F(CF₂)₆CH₂ (OCH₂C₂H₄)₆OH) was obtained as a pale brown liquid in an amount of 1.71 g (2.78 mmol, yield: 14%).

### Example 1

### (1) Photocurable Composition

The following reagents were blended:

<Photocurable component> 1,6-Hexanediol diacrylate (manufactured by Osaka Organic Chemical Industry Ltd.): 100 parts by weight
<Curing aid> Irgacure 369 (manufactured by Ciba Japan K.K.): 3 parts by weight
<Surface active agent> Surface active agent (C-1): 2 parts by weight

Next, a mixed solution obtained by blending the above-described reagents was filtered by a 0.2 μm tetrafluoroethylene filter, so as to prepare a photocurable composition (a-1).

The surface tension of the photocurable composition (a-1) measured by using an automatic surface tension balance CBVP-A3 (manufactured by Kyowa Interface Science Co., Ltd.) was 21 mN/m. Furthermore, the viscosity of the photocurable composition (a-1) measured by using a cone-plate rotational viscometer RE-85L (manufactured by Toki Sangyo Co., Ltd.) was 6.48 cP.

Next, a photocured product was prepared by the following method.

### (2) Applying Step

Onto a 4-inch silicon wafer having an adhesion accelerating layer with a thickness of 60 nm formed thereon as an adherent layer, the photocurable composition (a-1) was dropped by 15 μl with a micro-pipette.

### (3) Curing Step

Next, a quartz mold (with a width of 40 mm and a length of 40 mm) having been subjected to no surface treatment and having no pattern thereon was brought into contact with a surface of the silicon wafer.

Subsequently, the photocurable composition was irradiated, through the quartz mold, with UV rays by using a UV light source equipped with a 200-W mercury xenon lamp (EXECURE 3000, manufactured by HOYA CANDEO OPTRONICS CORPORATION). In the irradiation with the UV rays, an interference filter (VPF-50C-10-25-36500, manufactured by Sigma Koki Co., Ltd.) was disposed between the UV light source and the quartz mold. Furthermore, the illuminance of the UV rays directly below the quartz mold was 1 mW/cm² at a wavelength of 365 nm. The irradiation with UV rays was conducted for 60 seconds under these conditions.

### (4) Mold Releasing Step

Next, the quartz mold was pulled up under condition of 0.5 mm/s, so as to remove the mold from a photocured product.

In the aforementioned steps, the photocured product was obtained.

### (5) Evaluation of Photocured Product

Next, the photocured product obtained as described above was subjected to the following measurements so as to evaluate physical properties thereof.

### (5-1) Measurement of Mold Releasing Force

A compact tension/compression load cell (LUR-A-200NSA1, manufactured by Kyowa Electronic Instruments Co., Ltd.) was used for measuring force required for releasing a mold. In actual measurement, the mold releasing force was measured under the same conditions by 4 times, and a result obtained in the 4th measurement is shown in Table 1.

### (5-2) AR-XPS Measurement

Out of the photocured products obtained after performing the measurement of mold releasing force described in item (5-1) above, the surface of the photocured product obtained after the 4th measurement was subjected to the AR-XPS measurement. An XPS analysis apparatus and measurement conditions employed in this AR-XPS measurement are as follows:

Analysis apparatus: Photoelectron spectroscope (trade name: Quantera SXM, manufactured by Ulvac-Phi, Inc.)
Monochromatic X-ray source: Monochromatic aluminum Kα radiation
Spectroscope: Electrostatic concentric hemispherical analyzer
Ultimate pressure in measurement: 1×10⁻⁸ Torr or less

### Neutralization Ar ion gun: ON

Neutralization electron gun: ON
TOA: 7 degrees

Next, the sample (the photocured product) was irradiated with X-rays with a beam diameter of 500 μm×500 μm, so as to perform high resolution measurement for F1s, C1s and O1s in this order. Next, analysis software (manufactured by Ulvac-Phi, Inc., analysis software Multi Pack) was used for performing peak resolution of the obtained spectra. Among peaks thus resolved, peak areas of the ester bond derived peak and the ether bond derived peak were calculated, so as to evaluate an area ratio between these peaks (a peak area ratio calculated on the assumption that the peak area of the ester bond derived peak is 1). The result is shown in Table 1.

### Example 2

A photocurable composition (a-2) was prepared in the same manner as in Example 1 except that the amount of the surface active agent blended in Example 1 was changed to 5 parts by weight. The surface tension of the photocurable composition (a-2) measured in the same manner as in Example 1 was 25.5 mN/m. Furthermore, the viscosity of the photocurable composition (a-2) measured in the same manner as in Example 1 was 6.42 cP.

Moreover, a photocured product was prepared in the same manner as in Example 1. Besides, the mold releasing force was measured 4 times in the same manner as described in item (5-1) of Example 1, and a result obtained in the 4th measurement is shown in Table 1. Out of photocured products obtained after the measurement of the mold releasing force, the photocured product obtained after the 4th measurement was subjected to the AR-XPS measurement. The result is shown in Table 1.

### Example 3

A photocurable composition (a-3) was prepared in the same manner as in Example 1 except that the amount of the surface active agent blended in Example 1 was changed to 0.5 parts by weight. The surface tension of the photocurable composition (a-3) measured in the same manner as in Example 1 was 25.5 mN/m. Furthermore, the viscosity of the photocurable composition (a-3) measured in the same manner as in Example 1 was 6.42 cP.

Moreover, a photocured product was prepared in the same manner as in Example 1. Besides, the mold releasing force was measured 4 times in the same manner as described in item (5-1) of Example 1, and a result obtained in the 4th measurement is shown in Table 1. Out of photocured products obtained after the measurement of the mold releasing force, the photocured product obtained after the 4th measurement was subjected to the AR-XPS measurement. The result is shown in Table 1.

### Comparative Example 1

A photocurable composition (b-1) was prepared in the same manner as in Example 1 except that a surface active agent (C-2) was used as the surface active agent instead of the surface active agent (c-1) in Example 1. The surface tension of the photocurable composition (b-1) measured in the same manner as in Example 1 was 19.5 mN/m. Furthermore, the viscosity of the photocurable composition (b-1) measured in the same manner as in Example 1 was 6.45 cP.

Moreover, a photocured product was prepared in the same manner as in Example 1. Besides, the mold releasing force was measured 4 times in the same manner as described in item (5-1) of Example 1, and a result obtained in the 4th measurement is shown in Table 1. Out of photocured products obtained after the measurement of the mold releasing force, the photocured product obtained after the 4th measurement was subjected to the AR-XPS measurement. The results are shown in Table 1.

### Comparative Example 2

A photocurable composition (b-2) was prepared in the same manner as in Example 1 except that no surface active agent was blended in Example 1. The surface tension of the photocurable composition (b-2) measured in the same manner as in Example 1 was 35.9 mN/m. Furthermore, the viscosity of the photocurable composition (b-2) measured in the same manner as in Example 1 was 6.34 cP.

Moreover, a photocured product was prepared in the same manner as in Example 1. Besides, the mold releasing force was measured 4 times in the same manner as described in item (5-1) of Example 1, and a result obtained in the 4th measurement is shown in Table 1. Out of photocured products obtained after the measurement of the mold releasing force, the photocured product obtained after the 4th measurement was subjected to the measurement of the AR-XPS measurement. The results are shown in Table 1.

TABLE 1

| | | | | Com- | Com- |
|---|---|---|---|---|---|
| | | | | parative | parative |
| | Example 1 | Example 2 | Example 3 | Example 1 | Example 2 |
| Surface | C-1 | C-1 | C-1 | C-2 | (None) |
| active | 2 parts | 5 parts | 0.5 | 2 parts by | |
| agent | by | by | parts | weight | |
| | weight | weight | by | | |
| | | | weight | | |
| Mold | 98 | 132 | 135 | 155 | 162 |
| releasing | | | | | |
| force | | | | | |
| (mN/m) | | | | | |
| Ether | 12.9 | 5.5 | 4.2 | 2.8 | 1.2 |
| bond/ester | | | | | |
| bond (note | | | | | |
| 1) | | | | | |
| Evaluation | ∘ | ∘ | ∘ | x | x |
| for | | | | | |
| defects (note | | | | | |
| 2) | | | | | |

(note 1) A ratio in the peak area between the ether bond derived peak and the ester bond derived peak obtained by the AR-XPS measurement (a ratio calculated on the assumption that the peak area of the ester bond derived peak is 1).
(note 2) ∘: No defects found in observation of photocured product with optical microscope x: Some defects found in observation of photocured product with optical microscope

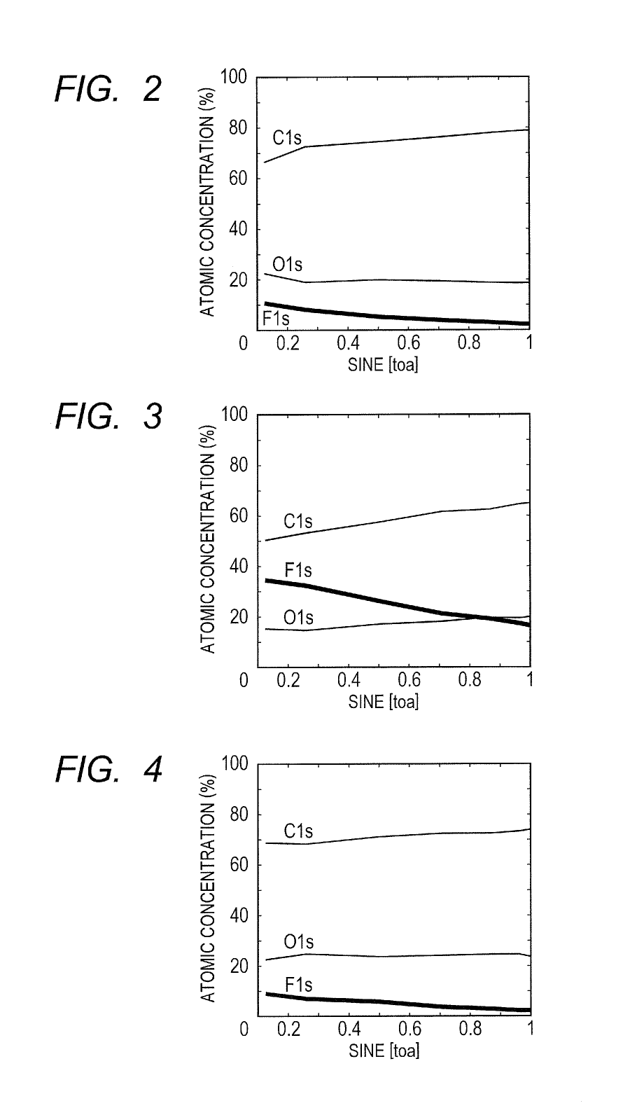

FIGS. 2 to 4 are diagrams illustrating the results of the AR-XPS measurement along the depth direction in the photocured products prepared in Examples 1 and 2 and Comparative Example 1, respectively. The photocured products were examined based on Table 1 and FIGS. 2 to 4.

When Example 1 and Comparative Example 1 are compared with each other based on FIGS. 2 and 4 and Table 1, although the content of the surface active agent is the same and a depth-direction distribution and a surface concentration of fluorine atoms included in the surface active agent are substantially the same, the mold releasing force was smaller in Example 1. Furthermore, a C—O—C/O—C═O ratio obtained by the AR-XPS analysis was larger in Example 1 than in Comparative Example 1. This reveals that a surface active agent having an ethylene oxide unit is superior to a surface active agent having a propylene oxide unit for reducing the mold releasing force.

When Examples 1 and 2 are compared with each other based on FIGS. 2 and 3 and Table 1, although the content of the surface active agent is larger in Example 2, the mold releasing force is smaller than in Example 1. Furthermore, the C—O—C/O—C═O ratio was smaller in Example 2 than in Example 1. This reveals that the effect of reducing the mold releasing force is varied according to the content of the surface active agent having ethylene oxide (and a fluorine atom-containing substituent) included in the photocurable composition. In other words, the effect of reducing the mold releasing force is not in proportion to the content of the surface active agent, but the effect of reducing the mold releasing force is increased if the surface active agent is included in a proper amount and even when the content of the surface active agent is large, if the amount is off the range of the proper amount, the effect of reducing the mold releasing force cannot be increased.

It was confirmed, based on Table 1, that the photocured product of Comparative Example 1 containing no surface active agent has larger mold releasing force than the photocured products of Examples and Comparative Example 1

Referring to Table 1, when the state of defects caused in detaching with a quartz mold having a line and space pattern used was evaluated with an optical microscope, a large number of defects were observed in the photocured products of Comparative Examples (1 and 2), which were rated as no good (X in Table 1).

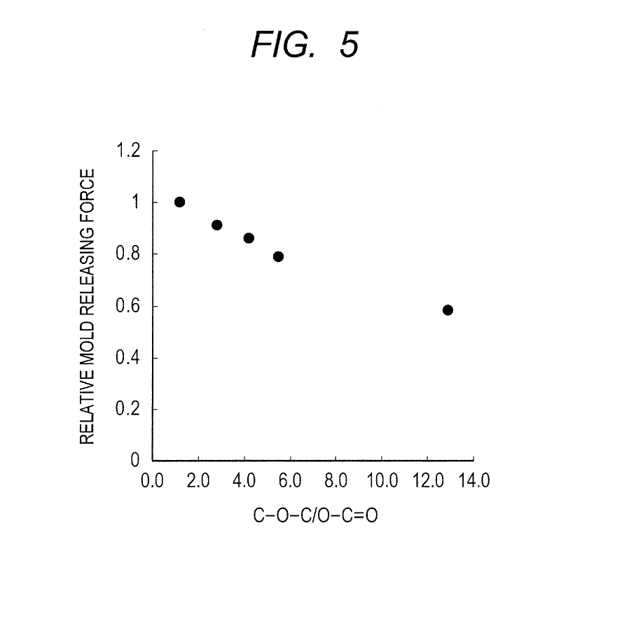

FIG. 5 is a graph illustrating the relationship between a peak area ratio (C—O—C/O—C═O) obtained based on the AR-XPS measurement and the mold releasing force of a layered body. Incidentally, the graph of FIG. 5 is obtained based on the results of Examples and Comparative Examples. FIG. 5 shows that as the peak area ratio (C—O—C/O—C═O) obtained based on the AR-XPS measurement is larger, the mold releasing force is smaller. Accordingly, it was revealed that a photocured product having a larger ratio of C—O—C/O—C═O has smaller mold releasing force.

Based on these examinations, it was revealed that the reduction of the mold releasing force is more largely affected by the ratio of C—O—C/O—C═O obtained at surface of a photocured product (the peak area ratio obtained based on the AR-XPS measurement) than by the amount of fluorine present at surface of the photocured product. This accords with the results of evaluation for defects shown in Table 1 in which a photocured product having a ratio of C—O—/O—C═O smaller than at least 2.9 was rated as no good.

### REFERENCE SIGNS LIST

1 photocurable composition
2 substrate
3 mold
10 coat film
11 photocured product

### ADVANTAGEOUS EFFECTS OF INVENTION

The present invention can provide a photocured product having small mold releasing force.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-126821, filed Jun. 4, 2012, which is hereby incorporated by reference herein in its entirety.

1. A photocured product obtained by curing with light, comprising a surface active agent,
wherein a peak area of an ether bond derived peak is at least 3.0 times large as a peak area of an ester bond derived peak, wherein the peak areas are obtained by peak separation processing by curve fitting of an X-ray photoelectron spectroscopy spectrum obtained as an analytical result of a chemical state of carbon at a topmost surface of the photocured product, the analytical result being among analytical results on the topmost surface of the photocured product obtained by a surface analysis of the photocured product with angle resolved X-ray photoelectron spectroscopy.

2. The photocured product according to claim 1, wherein the peak area of the ether bond derived peak is at least 4 times large as the peak area of the ester bond derived peak.

3. The photocured product according to claim 1, wherein the peak area of the ether bond derived peak is from 4 times to 20 times as large as the peak area of the ester bond derived peak.

4. The photocured product according to claim 1, wherein the surface active agent is a nonionic surface active agent.

5. The photocured product according to claim 1, wherein the surface active agent is a cationic surface active agent.

6. The photocured product according to claim 1, wherein the surface active agent is an anionic surface active agent.

7. The photocured product according to claim 1, wherein the surface active agent is a compound containing fluorine atoms.

8. The photocured product according to claim 1, wherein the surface active agent is a compound containing an ethylene oxide skeleton.

9. The photocured product according to claim 1, wherein the photocured product is obtained by curing with light after bringing into contact with a mold.

10. A photocurable composition comprising:
a photocurable component, wherein the photocurable component is cured with light;
a curing aid, wherein the curing aid aids curing of the photocurable component; and
a surface active agent,
wherein a photocured product according to claim 1 is obtained by irradiating the photocurable composition with light.

11. A method for producing a photocured product, comprising:
applying a photocurable composition onto a substrate;
bringing a mold having a prescribed pattern shape thereon into contact with the photocurable composition and curing the photocurable composition by irradiating the photocurable composition with light through the mold; and
releasing the photocurable composition from the mold,
wherein the photocurable composition is a photocurable composition according to claim 10.

12. A method for producing a circuit board, wherein a circuit is formed on a substrate by processing the substrate by using a mask obtained by processing a photocured product according to claim 1.

13. An optical component comprising:
a substrate; and
a member provided on the substrate and having a prescribed pattern shape,
wherein the member is a photocured product according to claim 1.

14. An electronic component comprising:
a substrate; and
an electronic member provided on the substrate,
wherein the substrate is a circuit board produced by a method according to claim 12.
